(19) United States
(12) Patent Application Publication
(10) Pub. No.: US 2025/0085406 A1
(43) Pub. Date: Mar. 13, 2025

(54) METHOD FOR OPERATING A TRANSMISSION DEVICE FOR ELECTROMAGNETIC SIGNALS, TRANSMISSION DEVICE, DETECTION DEVICE, AND VEHICLE

(71) Applicant: VALEO SCHALTER UND SENSOREN GMBH, Bietigheim-Bissingen (DE)

(72) Inventors: Christoph Parl, Bietigheim-Bissingen (DE); Johannes Appl, Bietigheim-Bissingen (DE); Wensi Zheng, Bietigheim-Bissingen (DE)

(73) Assignee: VALEO SCHALTER UND SENSOREN GMBH, Bietigheim-Bissingen (DE)

(21) Appl. No.: 18/294,782

(22) PCT Filed: Aug. 1, 2022
(86) PCT No.: PCT/EP2022/071505

§ 371 Date: Feb. 2, 2024

(30) Foreign Application Priority Data
Aug. 4, 2021 (DE) 10 2021 120 225.6

(51) Int. Cl. G01S 7/497; G01S 7/484; G01S 17/931

(52) U.S. Cl. CPC G01S 7/497; G01S 7/484; G01S 17/931

(57) ABSTRACT

A method for operating a transmission device for electromagnetic signals is disclosed. The method includes supplying at least one signal source with electric supply energy in order to emit electromagnetic signals. An influence of temperature on a transmission power of the at least one signal source is compensated for. In order to compensate for the influence of temperature, a signal duration of at least one electromagnetic signal is adapted on the basis of at least one temperature variable which characterizes a temperature of the at least one signal source.

### TECHNICAL FIELD

The invention relates to a method for operating a transmission device for electromagnetic signals, in which method at least one signal source is supplied with electric supply energy in order to emit electromagnetic signals, wherein an influence of temperature on a transmission power of the at least one signal source is compensated for.

Furthermore, the invention relates to a transmission device for electromagnetic signals, having at least one electrically operated signal source for emitting at least one electromagnetic signal and having at least one means for compensating for an influence of temperature on a transmission power of the at least one signal source.

Moreover, the invention relates to a detection apparatus for monitoring at least one monitoring region,
having at least one electrically operated signal source for emitting at least one electromagnetic signal,
having at least one means for compensating for an influence of temperature on a transmission power of the at least one signal source,
having at least one receiving device for receiving reflected electromagnetic signals and for converting them into electrical variables, and
having at least one control and evaluation device for controlling the detection apparatus and for evaluating electrical variables ascertained by the at least one receiving device.

In addition, the invention relates to a vehicle having at least one detection apparatus for monitoring at least one monitoring region, wherein the at least one detection apparatus has
at least one electrically operated signal source for emitting at least one electromagnetic signal,
at least one means for compensating for an influence of temperature on a transmission power of the at least one signal source,
at least one receiving device for receiving reflected electromagnetic signals and for
converting them into electrical variables, and
at least one control and evaluation device for controlling the detection apparatus and for evaluating electrical variables ascertained by the at least one receiving device.

### PRIOR ART

EP 1 039 597 B1 discloses a method for stabilizing the optical output power (light power) of light-emitting diodes and laser diodes, wherein the combination of diode current and forward voltage is used as a clear measure for the light power emitted by the light-emitting diode or laser diode, wherein it is presumed that independently of the temperature at constant light power the forward voltage is a function of the diode current, wherein the function via which the forward voltage results from the diode current at a particular constant light power is ascertained by measurements of diode current and forward voltage at constant light power at different temperatures and wherein for its stabilization the light-emitting diode or laser diode is operated in such a way that the functional relationship between forward voltage and diode current ascertained by the measurement is complied with.

The invention is based on the object of devising a method, a transmission device, a detection apparatus and a vehicle of the type mentioned above, in which the influence of temperature on the transmission power of the at least one signal source can be compensated for better, in particular more simply and/or more accurately.

### DISCLOSURE OF THE INVENTION

This object is achieved according to the invention with the method in that, in order to compensate for the influence of temperature, a signal duration of at least one electromagnetic signal is adapted on the basis of at least one temperature variable which characterizes a temperature of the at least one signal source.

The transmission energy of an emitted electromagnetic signal is all the greater, the greater the transmission power and the longer the signal duration for which the transmission power is emitted. For many signal sources, in particular for lasers, efficiency with regard to the transmission power is dependent on the temperature, in particular of the signal source. Accordingly, the transmission power and therefore also the transmission energy of an emitted electromagnetic signal changes with the temperature.

According to the invention, in order to compensate for the influence of temperature on the transmission power and thus on the transmission energy of an emitted electromagnetic signal, the signal duration of the at least one electromagnetic signal is adapted. In this way, a temperature-dependent change in the transmission power is compensated for by a corresponding change in the signal duration. This thus ensures that the emitted transmission energy is independent of the temperature of the at least one signal source.

The signal duration is adapted on the basis of at least one temperature variable. The at least one temperature variable characterizes a temperature of the at least one signal source. In this way, a measure for the temperature, in particular of the at least one signal source, can be ascertained using suitable temperature variables.

The at least one temperature variable can advantageously be realized by means of an electrical voltage value and/or an electrical current value. In this way, the at least one temperature variable can be processed electrically.

Advantageously, the at least one temperature variable can be realized with an analog value. In this way, the temperature variable can be ascertained and processed in an analog manner.

Alternatively or in addition, the at least one temperature variable can be realized with a digital value. In this way, the at least one temperature variable can be processed digitally.

For the compensation of the influence of temperature according to the invention, there is no need to adapt an energy source, in particular a current source, providing the electric supply energy. The invention makes it possible to simplify the complexity of control functions, in particular of a driver circuit for the at least one signal source.

In order to emit electromagnetic signals, the at least one signal source is supplied with electric supply energy. For this purpose, the at least one signal source can be arranged in a current path of an energy source, in particular of an electrical voltage source. The electric supply energy arises from the electrical voltage applied to the at least one signal source and from the electrical current flowing through the at least one signal source.

Advantageously, the at least one signal source can be used to transmit electromagnetic signals in the form of light signals, in particular laser signals. Light signals can be used to implement various functions, in particular signal time-of-flight measurements.

Advantageously, the at least one signal source can be used to transmit pulsed electromagnetic signals. Pulsed signals can be used to better carry out signal time-of-flight measurements.

Advantageously, the transmission device can be part of a detection apparatus for monitoring at least one monitoring region. In this way, the at least one monitoring region can be sampled more precisely, in particular reproducibly, using electromagnetic signals emitted according to the invention.

Advantageously, the detection apparatus can operate according to a signal time-of-flight method, in particular a signal pulse time-of-flight method. Detection apparatuses operating according to the signal pulse time-of-flight method can be configured and referred to as time-of-flight (TOF) systems, indirect time-of-flight (iTOF) systems, light detection and ranging (LiDAR) systems, laser detection and ranging (LaDAR) systems or the like.

Advantageously, the detection apparatus can be configured as a scanning system. In this case, a monitoring region can be sampled, that is to say scanned, using electromagnetic signals. For this purpose, the directions of propagation of the electromagnetic signals can be modified, in particular swiveled, over the monitoring region. In this case, at least one signal deflection device, in particular a scanning device, a deflection mirror device, or the like, can be used. Alternatively or in addition, the detection apparatus can be configured as a so-called flash system, in particular as flash LiDAR. In this case, appropriately spread electromagnetic signals can simultaneously irradiate a relatively large part of the monitoring region or the entire monitoring region.

Advantageously, the detection apparatus can be configured as a laser-based distance measurement system. Laser-based distance measurement systems can have lasers, in particular diode lasers, as signal sources. Lasers can be used to transmit in particular pulsed laser beams as electromagnetic signals. Lasers can be used to emit electromagnetic signals in wavelength ranges that are visible or not visible to the human eye. Accordingly, receivers of the detection apparatus can have or consist of sensors designed for the wavelength of the emitted electromagnetic signals, in particular point sensors, line sensors and/or surface sensors, in particular (avalanche) photodiodes, photodiode lines, CCD sensors, active pixel sensors, in particular CMOS sensors, or the like. Laser-based distance measurement systems can advantageously be configured as laser scanners. Laser scanners can be used to sample monitoring regions using in particular pulsed laser signals, in particular laser beams.

The invention can advantageously be used in vehicles, in particular motor vehicles. The invention can advantageously be used in land vehicles, in particular passenger vehicles, trucks, buses, motorcycles or the like, aircraft, in particular drones, and/or watercraft. The invention can also be used in vehicles that can be operated autonomously or at least semiautonomously. However, the invention is not restricted to vehicles. It can also be used in stationary operation, in robotics and/or in machines, in particular construction or transport machinery, such as cranes, excavators or the like.

The detection apparatus can advantageously be connected to at least one electronic control apparatus of a vehicle or of a machine, in particular to a driver assistance system, or can be part of such a control apparatus. In this way, at least some of the functions of the vehicle or of the machine can be performed autonomously or semiautonomously.

The detection apparatus can be used for detecting stationary or moving objects, in particular vehicles, persons, animals, plants, obstacles, roadway irregularities, in particular potholes or rocks, roadway boundaries, traffic signs, open spaces, in particular parking spaces, precipitation or the like, and/or movements and/or gestures.

In one advantageous configuration of the method, the at least one signal source can be supplied with electric supply energy having a pulsed power curve
and/or a supply duration for which the at least one signal source is supplied with electric supply energy can be adapted on the basis of the at least one temperature variable in order to adapt the signal duration of at least one electromagnetic signal.

Advantageously, the at least one signal source can be supplied with electric supply energy having a pulsed power curve. In this case, the pulsed power curve can be realized by electrical current pulses. For this purpose, an electrical supply path for the at least one signal source can be switched in a pulsed manner. In this way, use can be made of a simple voltage controller and/or current controller for the supply path, which controller only has to be controlled between a switched-on state and a switched-off state.

Alternatively or in addition, a supply duration for which the at least one signal source is supplied with electric supply energy can be used to adapt the signal duration of at least one electromagnetic signal on the basis of the at least one temperature variable. In this way, the signal duration can be adapted by means of the controller of the electric supply energy.

Advantageously, at least one electromagnetic signal can have at least one signal pulse. In this way, the electromagnetic signal is emitted for the duration of the at least one signal pulse.

Advantageously, at least one electromagnetic signal can have a plurality of signal pulses which are transmitted over the signal duration. Using pulsed electromagnetic signals makes it possible to reduce the heating of the at least one signal source during operation. The signal duration can thus also be specified by the number of the signal pulses.

In a further advantageous configuration of the method,
the electric supply energy for the at least one signal source can be controlled using at least one, in particular pulsed, trigger signal
and/or a trigger signal duration of at least one trigger signal for controlling the electric supply energy for the at least one signal source can be adapted on the basis of the at least one temperature variable.

A trigger signal can be realized in a simple manner, in particular digitally. Pulsed trigger signals are suitable for the pulsed activation of the at least one signal source. In this way, pulsed electromagnetic signals can be emitted.

Alternatively or in addition, the trigger signal duration of at least one trigger signal can be adapted on the basis of the at least one temperature variable. In this way, the signal duration of the electromagnetic signal can already simply be predefined by the control device.

Advantageously, at least one trigger signal can be a periodic signal, in particular a square-wave signal, a triangular signal, a sinusoidal signal, a sawtooth-shaped signal or the like. Periodic signals can be realized in a simple manner and reproducibly. Square-wave signals, triangular signals, sinusoidal signals and sawtooth-shaped signals can be defined in a simple manner.

In a further advantageous configuration of the method,
the signal duration of at least one electromagnetic signal can be adapted by the number of pulses of a pulsed power curve of the electric supply energy
and/or the signal duration of at least one electromagnetic signal can be adapted by the number of pulses of a pulsed trigger signal for controlling the supply energy for the at least one signal source. In this way, in particular in the case of a periodic power curve of the electric supply energy and/or a periodic trigger signal, the signal duration and therefore the output power of the at least one signal source can be adapted in a simple manner.

In a further advantageous configuration of the method,
the signal duration of at least one electromagnetic signal can be adapted by means of at least one correction variable predefined for the prevailing temperature
and/or the signal duration of at least one electromagnetic signal can be adapted by means of a correction variable predefined for the present at least one temperature variable. In this way, a relationship between the prevailing temperature, or rather the at least one temperature variable, and the signal duration required for compensating for the corresponding influence of temperature can be realized in a simple manner.

Advantageously, at least one correction variable can be a factor by which a variable that predefines the signal duration, in particular a predefined basic trigger signal duration and/or a predefined basic signal duration for the at least one electromagnetic signal, can be adapted.

Advantageously, a basic signal duration and/or a basic trigger signal duration which delivers a desired transmission energy for electromagnetic signals can be predefined for operation at an optimal temperature. In the case of deviations from the optimal temperature, the basic signal duration and/or the basic trigger signal duration can be adapted using the correction variable belonging to the actually prevailing temperature, in particular by multiplication. If, in the case of a temperature which deviates from the optimal temperature, the efficiency of the signal source and therefore the signal output power decreases, the basic signal duration and/or the basic trigger signal duration can be multiplied by the appropriate correction variable, and as a result the signal duration or the trigger signal duration can be lengthened.

Advantageously, a relationship between the temperature, in particular the at least one temperature variable, and at least one correction variable can be stored in advance in a lookup table in particular for the at least one signal source. It is thus possible to ascertain the correction variables quickly.

The relationship between the temperature, in particular the at least one temperature variable, and at least one correction variable, in particular at least one lookup table, can advantageously be stored in a corresponding storage medium of the at least one transmission device and/or of the detection apparatus. Advantageously, a relationship known for the signal source can be predefined.

Alternatively or in addition, the relationship can be ascertained by means of at least one test measurement, in particular at the end of the production line. In this way, the relationship can be determined in a simple manner.

In a further advantageous configuration of the method,
at least one temperature variable can be ascertained during operation of the at least one transmission device
and/or at least one temperature variable can be ascertained using at least one sensor
and/or at least one temperature variable can be ascertained from at least one supply energy variable, in particular a supply current and/or a supply voltage, for supplying power to the at least one signal source.

The at least one temperature variable which characterizes the present temperature can be ascertained during operation of the at least one transmission device.

Alternatively or in addition, at least one temperature variable can be ascertained using at least one sensor. In this way, the at least one temperature variable can be ascertained directly.

Alternatively or in addition, at least one temperature variable can be ascertained from at least one supply energy variable. In this way, a separate temperature sensor can be dispensed with. The at least one temperature variable can advantageously be ascertained from a supply current for the at least one signal source and/or from a supply voltage.

Furthermore, the object is achieved according to the invention with the transmission device in that the transmission device has at least one means for adapting a signal duration of at least one electromagnetic signal on the basis of at least one temperature variable characterizing a temperature of the at least one signal source.

According to the invention, at least one means can be used to adapt the signal duration of at least one electromagnetic signal on the basis of a temperature variable characterizing the temperature of the at least one signal source.

Advantageously, the transmission device and/or a detection apparatus having the transmission device has at least one means for carrying out the method according to the invention.

Advantageously, at least one means for carrying out the method according to the invention, in particular for adapting a signal duration on the basis of at least one temperature, can be implemented by way of software and/or hardware, in particular using the transmission device and/or the detection apparatus comprising the transmission device. In this way, components and/or functions that are present anyway can be used for implementing the invention.

In one advantageous embodiment,
at least one, in particular triggerable, control element, in particular at least one transistor, can be arranged in at least one energy supply path of the at least one signal source and/or at least one signal generator can be provided in order to generate at least one trigger signal for controlling at least one control element which is located in at least one energy supply path of the at least one signal source.

A control element can be used to control, in particular to close and open, the at least one energy supply path of the at least one signal source.

A triggerable control element can be actuated by means of trigger signals in order to close and open the energy supply path.

Advantageously, at least one control element can have or consist of at least one transistor. A transistor can be controlled, in particular switched, using trigger signals in a simple manner.

Alternatively or in addition, at least one signal generator can be provided. A signal generator can be used to generate trigger signals. The trigger signals can be transmitted to the at least one control element.

Advantageously, the transmission device and/or the detection apparatus comprising the transmission device can have at least one signal generator. In this way, a compact design can be realized.

In a further advantageous embodiment, the transmission device can have at least one means for implementing a variable characterizing the signal duration, on the basis of the at least one temperature variable.

Advantageously, the signal duration of a trigger signal can be a variable which characterizes the signal duration of the at least one electromagnetic signal. In this way, the signal duration of the at least one electromagnetic signal can be predefined using the trigger signal.

Alternatively or in addition, the number of pulses of a trigger signal can be a variable characterizing the signal duration. In this way, the signal duration of the at least one electromagnetic signal can be predefined using discrete values.

Moreover, the object is achieved according to the invention with the detection apparatus in that the detection apparatus has at least one means for adapting a signal duration of at least one electromagnetic signal on the basis of at least one temperature variable characterizing a temperature of the at least one signal source.

Depending on the application of the detection apparatus, in particular as an indirect time-of-flight system or as another type of LiDAR system, an electromagnetic signal, in particular a light signal, having a plurality of signal pulses, in particular light pulses, can be emitted within one measurement in order to generate a defined transmission energy, in particular a defined light energy.

Additionally, the object is achieved according to the invention with the vehicle in that the detection apparatus has at least one means for adapting a signal duration of at least one electromagnetic signal on the basis of at least one temperature variable characterizing a temperature of the at least one signal source.

According to the invention, the vehicle has at least one detection apparatus which can be used to monitor a monitoring region. In this way, objects in the monitoring region can be detected.

Advantageously, the at least one detection apparatus can be used to monitor at least one monitoring region outside the vehicle and/or inside the vehicle, in particular for objects. In this way, information about objects in the surroundings of the vehicle or in the vehicle can be ascertained.

Advantageously, the vehicle can have at least one driver assistance system. A driver assistance system can be used to operate the vehicle autonomously or semiautonomously.

Advantageously, at least one detection apparatus can be functionally connected to at least one driver assistance system. In this way, information about a monitoring region, in particular object information, which is obtained using the at least one detection apparatus, can be used by the at least one driver assistance system for controlling autonomous or semiautonomous operation of the vehicle.

Moreover, the features and advantages indicated in connection with the method according to the invention, the transmission device according to the invention, the detection apparatus according to the invention and the vehicle according to the invention and the respective advantageous configurations thereof apply in a mutually corresponding manner and vice versa. The individual features and advantages can of course be combined with one another, wherein further advantageous effects that go beyond the sum of the individual effects may result.

### BRIEF DESCRIPTION OF THE DRAWINGS

Further advantages, features and details of the invention will become apparent from the following description, in which exemplary embodiments of the invention are explained in more detail with reference to the drawing. A person skilled in the art will expediently also consider individually the features that have been disclosed in combination in the drawing, the description and the claims and will combine them to form meaningful further combinations. In the schematic figures,

FIG. 1 shows a front view of a vehicle having a driver assistance system and a LiDAR system for detecting objects in the direction of travel in front of the vehicle;

FIG. 2 shows a block diagram of the vehicle having the driver assistance system and the LiDAR system from FIG. 1;

FIG. 3 shows a circuit diagram of a transmission device of the LiDAR system from FIGS. 1 and 2 according to a first exemplary embodiment;

FIG. 4 shows a time characteristic of a trigger signal having a basic signal duration for actuating a laser of the transmission device from FIG. 3;

FIG. 5 shows a time characteristic of the trigger signal from FIG. 4 having twice the basic signal duration;

FIG. 6 shows a diagram in which the efficiency of the laser of the transmission device from FIG. 3 is illustrated as a function of the temperature of the laser;

FIG. 7 shows a diagram in which a dependency of a correction factor, which is used to compensate for the temperature dependency of the efficiency of the laser from FIG. 3, on the temperature of the laser is illustrated;

FIG. 8 shows a diagram in which the laser transmission energy of a laser signal transmitted by the laser of the transmission device from FIG. 3 is illustrated as a function of the temperature of the laser, wherein the temperature dependency of the efficiency is compensated for using the temperature-dependent correction factor in accordance with FIG. 7;

FIG. 9 shows a diagram in which the laser transmission energy of a laser signal transmitted by the laser of the transmission device from FIG. 3 is illustrated as a function of the temperature of the laser, wherein temperature dependency of the efficiency is not compensated for;

FIG. 10 shows a circuit diagram of a transmission device of the LiDAR system from FIGS. 1 and 2 according to a second exemplary embodiment.

In the figures, identical elements are provided with identical reference signs.

### EMBODIMENT(S) OF THE INVENTION

FIG. 1 shows the front view of a vehicle 10, for example in the form of a passenger vehicle.

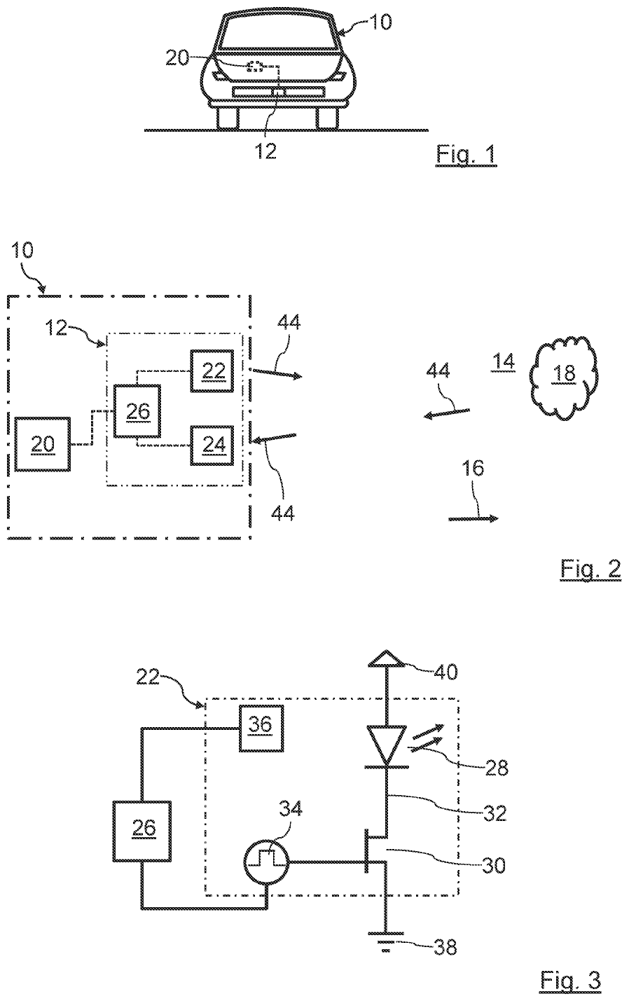

The vehicle 10 has a detection apparatus, for example in the form of a LiDAR system 12. FIG. 2 shows a block diagram of the vehicle 10 having the LiDAR system 12.

By way of example, the LiDAR system 12 is arranged in the front bumper of the vehicle 10. The LiDAR system 12 can be used to monitor a monitoring region 14 in the direction of travel 16 in front of the vehicle 10 for objects 18. The LiDAR system 12 can also be arranged at another point on the vehicle 10 and oriented differently. The LiDAR system 12 can also be arranged in the vehicle 10 to monitor an interior. The LiDAR system 12 can be used to ascertain object information, for example distances, directions and speeds of objects 18 relative to the vehicle 10, or rather to the LiDAR system 12, or corresponding characterizing variables. The LiDAR system 12 can also be used to detect gestures, for example of persons.

The objects 18 can be stationary or moving objects, for example other vehicles, persons, animals, plants, obstacles, roadway irregularities, for example potholes or rocks, roadway boundaries, traffic signs, open spaces, for example parking spaces, precipitation or the like.

The LiDAR system 12 is connected to a driver assistance system 20 of the vehicle 10. The driver assistance system 20 can be used to operate the vehicle 10 autonomously or semiautonomously.

The LiDAR system 12 comprises, by way of example, a transmission device 22, a receiving device 24 and a control and evaluation device 26.

The functions of the control and evaluation device 26, of the transmission device 22 and of the receiving device 24 can be implemented at least partially in a centralized manner or in a decentralized manner. Parts of the functions and/or corresponding components of the control and evaluation device 26 can also be integrated in the transmission device 22 and/or the receiving device 24 and vice versa. The control and evaluation device 26 and the driver assistance system 20 may also be partially combined. The functions of the transmission device 22, of the receiving device 24 and of the control and evaluation device 26 are implemented by way of software and hardware.

FIG. 3 shows a circuit diagram of a transmission device 22 according to a first exemplary embodiment in connection with the control and evaluation device 26.

The transmission device 22 comprises a signal source in the form of a laser 28, a control element in the form of a transistor 30 for a current path 32 of the laser 28, a signal generator 34 for generating trigger signals 42 for triggering the control element 30, and a temperature detection device 36 for detecting a temperature of the laser 28.

The current path 32 forms an energy supply path for the laser 28. The current path 32 of the laser 28 is on one side connected to ground 38 via the control element 30 and on the other side connected to a voltage source 40. The voltage source 40 forms an energy supply device which can be used to supply the laser 28 with electric supply energy. The voltage source 40 can for example be a centralized voltage supply of the LiDAR system 12.

The base of the transistor 30 is connected to a signal output of the signal generator 34. The emitter and collector of the transistor 30 are located in the current path 32. The current path 32 can be closed and opened by appropriate actuation of the transistor 30.

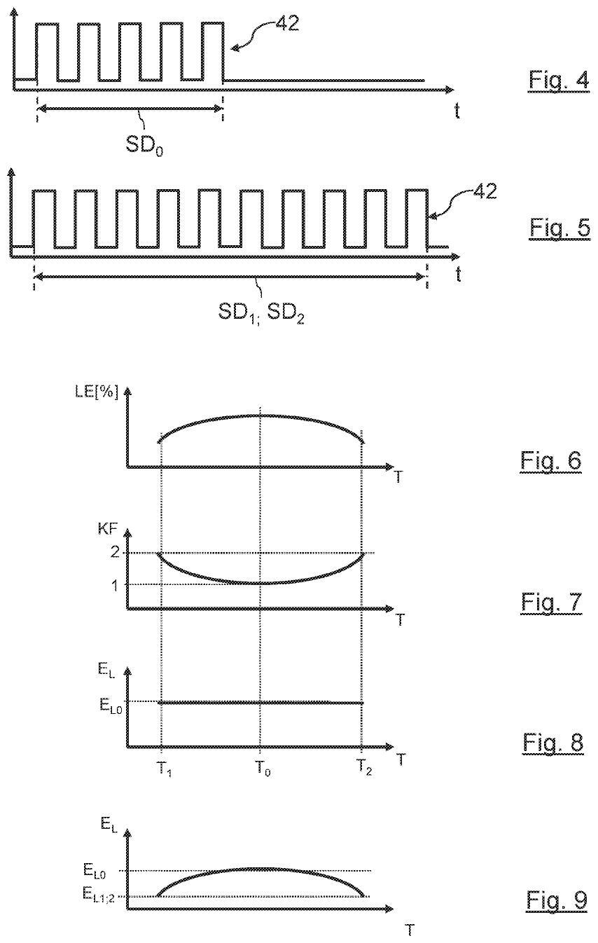

A control input of the signal generator 34 is connected to the control and evaluation device 26. The control and evaluation device 26 can be used to actuate the signal generator 34 via the control input in order to generate trigger signals 42. FIG. 4 illustrates, by way of example, such a trigger signal 42 having the basic signal duration SD₀. The trigger signal 42 is, by way of example, a pulsed signal, by way of example a square-wave signal. FIG. 5 shows a trigger signal 42 having the signal duration SD₁ or SD₂, respectively.

The trigger signal 42 is used to actuate the transistor 30 in a pulsed manner such that the current path 32 is accordingly closed in a pulsed manner. The laser 28 is thus supplied with electric supply energy having a pulsed power curve. The laser 28 is used to generate a pulsed laser signal 44 in accordance with the pulse curve and the signal duration SD of the trigger signal 42. The generated pulsed laser signal 44 has a signal duration SD which corresponds to the trigger signal duration SD of the trigger signal 42. The trigger signal duration and the signal duration of the laser signal 44 are therefore designated by the reference sign “SD” below.

The temperature detection device 36 comprises a temperature sensor arranged in the vicinity of the laser 28. The temperature detection device 36 can be used to ascertain a temperature variable characterizing the temperature of the laser 28, for example an electrical voltage value or a digital value. The temperature detection device 36 is connected to the control and evaluation device 26. In this way, the ascertained temperature variables can be transmitted to the control and evaluation device 26.

By way of example, the laser 28 is implemented as a diode laser. As shown by way of example in FIG. 6, a laser efficiency LE of the laser 28 is dependent on the temperature of the laser 28. The laser efficiency LE influences the laser transmission energy EL, that is to say the light energy, of a transmitted laser signal 44, as shown in FIG. 9. In the case of an optimal temperature T₀ with regard to the laser efficiency LE by way of example, the laser efficiency LE has its maximum. The laser efficiency LE decreases as the temperature deviates from the optimal temperature T₀, for example up to a lower limit temperature T₁ on the one hand and up to an upper limit temperature T₂ on the other hand. The lower limit temperature T₁ and the upper limit temperature T₂ are exemplary temperatures at which the laser 28 can usually be operated. In FIG. 6, the temperature curve of the laser efficiency LE is illustrated by way of example approximately symmetrically with regard to the optimal temperature T₀. The temperature curve of the laser efficiency LE and accordingly the temperature curve of the laser transmission energy E_{L} can also have another shape.

Starting from the optimal temperature T₀, as the temperature deviates, the laser transmission energy E_{L} respectively decreases in accordance with the temperature curve of the laser efficiency LE. The temperature curve of the laser transmission energy E_{L} corresponding to the temperature curve of the laser efficiency LE is shown in FIG. 9. FIG. 9 illustrates a diagram in which the laser transmission energy E_{L} of a transmission signal 44 transmitted by the laser 28 is illustrated as a function of the temperature of the laser 28.

The laser transmission energy E_{L} of a light signal 44 is proportional to the product of the laser output power, of the signal duration SD and of the duty cycle of the trigger signal 42. The trigger signal 42 is, by way of example, a square-wave signal having a duty cycle of 50%. Alternatively, the laser transmission energy E_{L} for a light signal 44 can be illustrated proportional to the number of the square-wave pulses of the trigger signal 42 within the signal duration SD. Starting from the optimal temperature T₀, the laser transmission energy E_{L} for the light signal 44 at a constant signal duration SD decreases as the temperature of the laser 28 increases or decreases, as shown in FIG. 9.

In order to be able to carry out precise and reproducible measurements using the LiDAR system 12, however, it is necessary to transmit laser signals 44 having as constant a laser transmission energy E_{L} as possible. This is achieved in the exemplary LiDAR system 12 in that the signal duration SD of the laser signal 44 is adapted on the basis of the temperature of the laser 28, or rather on the basis of the temperature variable characterizing the temperature. For this purpose, in the case of a temperature deviating from the optimal temperature T₀, a basic signal duration SD₀ is corrected, for example multiplied, by a correction factor KF for the prevailing temperature.

The basic signal duration SD₀ can for example be predefined such that the laser signal 44 is transmitted with a desired, for example predefined, laser transmission energy E_{L0} at the optimal temperature T₀. The correction factor KF for the prevailing temperature is taken for example from a lookup table. The relationship between the correction factors KF and the temperature is, by way of example, ascertained on the basis of the known or predetermined temperature curve of the laser efficiency LE for the laser 28.

The laser efficiency LE is individual for each laser 28 and can be ascertained in advance, for example in the course of test measurements or from specifications of the manufacturer. The curve of the laser efficiency LE is stored for example in a lookup table in the control and evaluation device 26.

The control and evaluation device 26 has means which can be used to ascertain a corresponding temperature curve of the correction factors KF, as is shown in FIG. 7, from the temperature curve of the laser efficiency LE shown for example in FIG. 6. Alternatively, the temperature curve of the correction factors KF can also be stored directly in a corresponding lookup table of the control and evaluation device 26.

With the aid of the correction factor KF assigned to the prevailing temperature, or rather to the corresponding temperature variable, it is possible to ascertain the required signal duration SD that makes it possible to compensate for the temperature dependency of the laser efficiency LE. The signal generator 34 is actuated for the ascertained signal duration SD in order to generate the trigger signal 42. The signal generator 34 for its part uses the trigger signal 42 to control the transistor 30 such that the laser 28 emits the correspondingly pulsed laser signal 44 over the signal duration SD with the corresponding laser transmission energy E_{L}.

By way of example, the correction factor KF=1 at the optimal temperature T₀. It increases moving toward the lower limit temperature T₁ and moving toward the upper limit temperature T₂ in each case until the correction factor KF=2. This means that, by way of example, if the lower limit temperature T₁ is present or if the upper limit temperature T₂ is present, the basic signal duration SD₀ of the trigger signal 42 and thus the signal duration of the laser signal 44 are each doubled, as shown in FIG. 5, to a signal duration SD₁ or SD₂, respectively. By adapting the signal duration SD on the basis of the temperature variable, a constant temperature curve for the laser transmission energy E_{L0} is achieved, as shown in FIG. 8.

The LiDAR system 12 can be configured as a scanning LiDAR system or as a flash LiDAR system. The transmission device 22 may optionally have at least one optical system, for example an optical lens, which can be used to correspondingly influence, in particular spread and/or focus, the generated laser signals 44.

Furthermore, the transmission device 22 may optionally have a signal deflection device, for example a mirror, which can be used to direct the laser signals 44 into the monitoring region 14. Deflecting parts of the signal deflection device may be modifiable, for example pivotable or rotatable relative to the laser 28. In this way, the directions of propagation of the laser signals 44 can be swiveled and the monitoring region 14 can be sampled or scanned. The laser signals 44 are transmitted into the monitoring region 14 using the transmission device 22.

The laser signals 44 reflected at an object 18 in the direction of the receiving device 24 are received by the receiving device 24. The receiving device 24 may optionally have, on its input side, a signal deflection device and/or an optical system, for example an optical lens or the like, which can be used to deflect the reflected laser signals 44 to a receiver of the receiving device 24.

By way of example, the receiver of the receiving device 24 can be configured as a point sensor, line sensor or surface sensor, for example as an (avalanche) photodiode, photodiode line, CCD sensor, active pixel sensor, in particular CMOS sensor, or the like. The receiver is used to convert the reflected laser signals 44 into electrical signals which can be transmitted to the control and evaluation device 26.

The electrical signals are processed using the control and evaluation device 26. For example, object variables, for example, distance variables, direction variables and/or speed variables, which characterize distances, directions and speeds, respectively, of detected objects 18 relative to the LiDAR system 12 and/or relative to the vehicle 10, are ascertained from the electrical signals by means of the control and evaluation device 26.

The ascertained object variables are transmitted to the driver assistance system 20 by means of the control and evaluation device 26. The driver assistance system 20 is used to use the object variables to operate the vehicle 10 autonomously or semiautonomously.

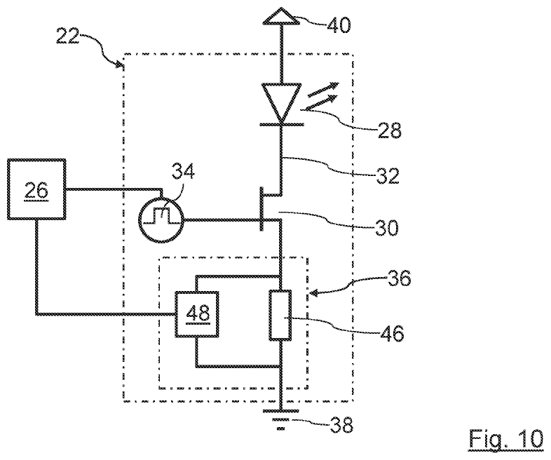

FIG. 10 shows a second exemplary embodiment of a transmission device 22 for the LiDAR system from FIGS. 1 and 2. Those elements which are similar to those of the first exemplary embodiment from FIG. 3 are provided with the same reference signs. The second exemplary embodiment differs from the first exemplary embodiment in that, instead of a temperature sensor, the temperature detection device 36 comprises an electrical resistor 46 and a measuring transducer 48. The electrical resistor 46 is arranged in the current path 32 of the laser 28. The measuring transducer 48 is used to convert the electrical voltage, which is applied to the electrical resistor 46 when the current path 32 is closed, into a corresponding signal which realizes a temperature variable which characterizes the temperature of the laser 28. The temperature variable is transmitted from the measuring transducer 48 to the control and evaluation device 26. The control and evaluation device 26 is used to actuate the signal generator 34 in the same way as in the first exemplary embodiment.

1. A method for operating a transmission device for electromagnetic signals,
the method comprising supplying at least one signal source with electric supply energy in order to emit electromagnetic signals,
wherein an influence of temperature on a transmission power of the at least one signal source is compensated for,
wherein, in order to compensate for the influence of temperature, a signal duration of at least one electromagnetic signal is adapted on the basis of at least one temperature variable which characterizes a temperature of the at least one signal source.

2. The method as claimed in claim 1,
wherein the electric supply energy has a pulsed power curve, and
wherein a supply duration of the electric supply energy is adapted on the basis of the at least one temperature variable in order to adapt the signal duration of at least one electromagnetic signal.

3. The method as claimed in claim 1, characterized in that wherein the electric supply energy for the at least one signal source is controlled using at least one pulsed, trigger signal, and
wherein a trigger signal duration of at least one trigger signal for controlling the electric supply energy for the at least one signal source is adapted on the basis of the at least one temperature variable.

4. The method as claimed in claim 1,
wherein the signal duration of at least one electromagnetic signal is adapted by the number of pulses of a pulsed power curve of the electric supply energy, and/or
wherein the signal duration of at least one electromagnetic signal is adapted by the number of pulses of a pulsed trigger signal for controlling the supply energy for the at least one signal source.

5. The method as claimed in claim 1,
wherein the signal duration of at least one electromagnetic signal is adapted by using at least one correction variable predefined for the prevailing temperature, and/or
wherein the signal duration of at least one electromagnetic signal is adapted by using a correction variable predefined for the present at least one temperature variable.

6. The method as claimed in claim 1,
wherein at least one temperature variable is ascertained during operation of the at least one transmission device,
wherein at least one temperature variable is ascertained using at least one sensor, and/or
wherein at least one temperature variable is ascertained from a supply current and/or a supply voltage, for supplying power to the at least one signal source.

7. A transmission device for electromagnetic signals, the transmission device comprising:
at least one electrically operated signal source for emitting at least one electromagnetic signal, and
at least one evaluating device, signal generator, or temperature detecting device for compensating for an influence of temperature on a transmission power of the at least one signal source,
wherein the at least one evaluating device, signal generator, or temperature detecting device is for adapting a signal duration of at least one electromagnetic signal on the basis of at least one temperature variable characterizing a temperature of the at least one signal source.

8. The transmission device as claimed in claim 7,
wherein at least one, in particular triggerable, control element, transistor, is arranged in at least one energy supply path of the at least one signal source, and
wherein at least one signal generator is provided in order to generate at least one trigger signal for controlling at least one control element which is located in at least one energy supply path of the at least one signal source.

9. The transmission device as claimed in claim 7, wherein the transmission device comprises at least one signal generator for implementing a variable characterizing the signal duration, on the basis of the at least one temperature variable.

10. A detection apparatus for monitoring at least one monitoring region, the detection apparatus comprising:
at least one electrically operated signal source for emitting at least one electromagnetic signal,
at least one evaluating device, signal generator, or temperature detecting device for compensating for an influence of temperature on a transmission power of the at least one signal source,
at least one receiving device for receiving reflected electromagnetic signals and for converting them into electrical variables, and
at least one control and evaluation device for controlling the detection apparatus and for evaluating electrical variables ascertained by the at least one receiving device,
wherein the detection apparatus comprises at least one evaluating device, signal generator, or temperature detecting device for adapting a signal duration of at least one electromagnetic signal on the basis of at least one temperature variable characterizing a temperature of the at least one signal source.

11. A vehicle comprising at least one detection apparatus for monitoring at least one monitoring region,
wherein the at least one detection apparatus comprises:
at least one electrically operated signal source for emitting at least one electromagnetic signal,
at least one means for compensating for an influence of temperature on a transmission power of the at least one signal source,
at least one receiving device for receiving reflected electromagnetic signals and for converting them into electrical variables, and
at least one control and evaluation device for controlling the detection apparatus and for evaluating electrical variables ascertained by the at least one receiving device,
wherein the detection apparatus comprises at least one evaluating device, signal generator, or temperature detecting device for adapting a signal duration of at least one electromagnetic signal on the basis of at least one temperature variable characterizing a temperature of the at least one signal source.
